(19) United States
(12) Patent Application Publication
(10) Pub. No.: US 2026/0182079 A1
(43) Pub. Date: Jun. 25, 2026

(54) Ga2O3 heterojunction based DUV sensor and method of fabricating the same

(71) Applicant: POWER CUBESEMI INC., Seongnam-si (KR)

(72) Inventors: Tai Young KANG, Gwangju-si (KR); Sin Su KYOUNG, Hanam-si (KR); Yu Sup JUNG, Osan-si (KR); Tae Jun Park, Seongnam-si (KR)

(73) Assignee: POWER CUBESEMI INC., Seongnam-si (KR)

(21) Appl. No.: 19/425,147

(22) Filed: Dec. 18, 2025

(30) Foreign Application Priority Data
Dec. 19, 2024 (KR) 10-2024-019177

(51) Int. Cl. H10F 77/20; H10F 30/222; H10F 77/12

(52) U.S. Cl. CPC H10F 77/241; H10F 30/222; H10F 77/12

(57) ABSTRACT

A gallium oxide heterojunction-based DUV sensor includes an n-type gallium oxide substrate; an n-type gallium oxide epitaxial layer epitaxially grown on the n-type gallium oxide substrate; a p-type nickel oxide layer formed on the n-type gallium oxide epitaxial layer and forming a pn heterojunction with the n-type gallium oxide epitaxial layer; a patterned top electrode formed on the p-type nickel oxide layer; and a bottom electrode formed under the n-type gallium oxide substrate.

### CROSS-REFERENCE TO RELATED APPLICATION

The present application claims priority under 35 U.S.C. § 119(a) to Korean application number 10-2024-0191777, filed on December 19, 2024, in the Korean Intellectual Property Office, which is incorporated herein by reference in its entirety.

### BACKGROUND

The present invention relates to a heterojunction based DUV (Deep UV) sensor.

UV sensors used in fire detectors include UVtron, which uses vacuum tubes, and the semiconductor photodiode, which uses Wide Bandgap (WBG) materials such as SiC and GaN. However, currently used UV sensors do not have the characteristics necessary for arc fire detection.

Arc fire detectors are primarily used in areas where electrical switchboards or equipment are monitored. These detectors require a sensor with a short sensing distance but capable of detecting an accurate arc wavelength range. Arc is known to generate deep ultraviolet (Deep-Ultraviolet, hereinafter DUV) in the 280~200nm wavelength range. Although WBG-based UV photosensors are more suitable for arc fire detectors than UVtron, their application is difficult due to noise problems such as low output current and reaction to UV-A and B. In addition, WBG-based UV photodiodes are about 20 times more expensive than the existing vacuum tube-based UVtron, making their application in fire detectors difficult.

### SUMMARY

According to one aspect of the present invention, there is provided a gallium oxide heterojunction-based DUV sensor, including an n-type gallium oxide substrate, an n-type gallium oxide epitaxial layer disposed on the n-type gallium oxide substrate, a p-type nickel oxide layer disposed on the n-type gallium oxide epitaxial layer and configured to form a pn heterojunction with the n-type gallium oxide epitaxial layer, a patterned top electrode disposed on the p-type nickel oxide layer, and a bottom electrode disposed on a bottom surface of the n-type gallium oxide substrate.

In one embodiment, the patterned top electrode may include a plurality of coaxial ring regions sharing a common central axis, a connecting region extending from an innermost coaxial ring region to an outermost coaxial ring region and electrically connected to each of the plurality of coaxial ring regions, and a pad region connected to a distal end of the connecting region, the distal end being farthest from the common central axis.

In one embodiment, the patterned top electrode may include a nickel-chromium alloy layer disposed on the p-type nickel oxide layer and configured to form an ohmic contact with the p-type nickel oxide layer and an aluminum-silicon alloy layer disposed on the nickel-chromium alloy layer.

In one embodiment, the aluminum-silicon alloy layer may have a weight ratio of aluminum to silicon of 99:1.

In one embodiment, the patterned top electrode may include a p-type contact resistance reducing layer disposed on the p-type nickel oxide layer and configured to reduce contact resistance, a nickel-chromium alloy layer disposed on the contact resistance reducing layer and an aluminum-silicon alloy layer disposed on the nickel-chromium alloy layer.

In one embodiment, the p-type contact resistance reducing layer may include a Li-doped nickel oxide layer having a carrier concentration greater than that of the p-type nickel oxide layer.

In one embodiment, the thickness of the p-type contact resistance reducing layer may be less than the thickness of the nickel-chromium alloy layer.

In one embodiment, the aluminum-silicon alloy layer may have a weight ratio of aluminum to silicon of 99:1.

In one embodiment, the bottom electrode may include a titanium layer disposed on the bottom surface of the n-type gallium oxide substrate and configured to form an ohmic contact and an aluminum-silicon alloy layer disposed on the titanium layer.

According to another aspect of the present invention, a method of manufacturing a gallium oxide heterojunction-based DUV sensor is provided, the method including providing an n-type gallium oxide substrate having an n-type gallium oxide epitaxial layer formed thereon, forming a bottom electrode on a bottom surface of the n-type gallium oxide substrate, forming a p-type nickel oxide layer on the n-type gallium oxide epitaxial layer, and forming a patterned top electrode on the p-type nickel oxide layer.

In one embodiment, the forming the patterned top electrode on the p-type nickel oxide layer may include forming a top electrode pattern on the p-type nickel oxide layer, the top electrode pattern including a plurality of coaxial ring regions, a connecting region connected to the plurality of coaxial ring regions, and a pad region connected to the connecting region, depositing a nickel-chromium alloy layer on the p-type nickel oxide layer via sputtering using a nickel-chromium alloy target, depositing an aluminum-silicon alloy layer on the nickel-chromium alloy layer via sputtering using an aluminum-silicon alloy target, and removing the top electrode pattern.

In one embodiment, the forming the patterned top electrode on the p-type nickel oxide layer may include forming a top electrode pattern on the p-type nickel oxide layer, the top electrode pattern including a plurality of coaxial ring regions, a connecting region connected to the plurality of coaxial ring regions, and a pad region connected to the connecting region, depositing a nickel-chromium alloy layer on the p-type nickel oxide layer via sputtering using a nickel-chromium alloy target, depositing an aluminum-silicon alloy layer on the nickel-chromium alloy layer via sputtering using an aluminum-silicon alloy target and removing the top electrode pattern.

In one embodiment, the forming the patterned top electrode on the p-type nickel oxide layer may include forming a top electrode pattern on the p-type nickel oxide layer, the top electrode pattern including a plurality of coaxial ring regions, a connecting region connected to the plurality of coaxial ring regions, and a pad region connected to the connecting region, depositing a p-type Li-doped nickel oxide layer on the p-type nickel oxide layer via sputtering using a Li-doped nickel oxide target, depositing a nickel-chromium alloy layer on the p-type Li-doped nickel oxide layer via sputtering using a nickel-chromium alloy target, depositing an aluminum-silicon alloy layer on the nickel-chromium alloy layer via sputtering using an aluminum-silicon alloy target and removing the top electrode pattern.

### BRIEF DESCRIPTION OF THE DRAWINGS

Hereinafter, embodiments of the invention will be described with reference to the accompanying drawings. For the purpose of easy understanding of the invention, the same elements will be referred to by the same reference signs. Configurations illustrated in the drawings are examples for describing the invention, and do not restrict the scope of the invention. Particularly, in the drawings, some elements are slightly exaggerated for the purpose of easy understanding of the invention. Since the drawings are used to easily understand the invention, it should be noted that widths, depths, and the like of elements illustrated in the drawings might change at the time of actual implementation thereof. Meanwhile, throughout the detailed description of the invention, the same components are described with reference to the same reference numerals.

FIG. 1 illustrates one embodiment of a gallium oxide heterojunction-based DUV sensor;

FIG. 2 illustrates a cross-section of one embodiment of the gallium oxide heterojunction-based DUV sensor along AA' of FIG. 1;

FIG. 3 is an I-V characteristic graph of the gallium oxide heterojunction-based DUV sensor illustrated in FIG. 2 under dark condition;

FIG. 4 illustrates a cross-section of one embodiment of the gallium oxide heterojunction-based DUV sensor along AA' of FIG. 1;

FIG. 5A, FIG. 5B, FIG. 5C, FIG. 6A, FIG. 6B, FIG. 6C, FIG. 7A and FIG. 7B illustrate a manufacturing process of a gallium oxide heterojunction-based DUV sensor;

FIG. 8A and FIG. 8B are graphs illustrating I-V characteristics of the gallium oxide heterojunction-based DUV sensor, as shown in FIG. 4, measured under dark conditions;

FIG. 9A and FIG. 9B are graphs illustrating exemplary photocurrent responses of the gallium oxide heterojunction-based DUV sensor as a function of UV wavelength;

FIG. 10 is a graph illustrating an exemplary responsivity of a gallium oxide heterojunction-based DUV sensor as a function of UV wavelength;

FIG. 11A and FIG. 11B are graphs illustrating exemplary photocurrent characteristics of the gallium oxide heterojunction-based DUV sensor as a function of temperature;

FIG. 12 is a graph illustrating I-V characteristics of the gallium oxide heterojunction-based DUV sensor under reverse bias conditions;

FIG. 13 is a graph illustrating the current characteristics of the gallium oxide heterojunction-based DUV sensor as a function of applied bias voltage;

FIG. 14 is a graph illustrating the photocurrent characteristics of the gallium oxide heterojunction-based DUV sensor as a function of the distance between the sensor and a light source; and

FIG. 15 is a graph illustrating the photocurrent characteristics of the gallium oxide heterojunction-based DUV sensor as a function of incident light wavelength.

### DETAILED DESCRIPTION

Embodiments of the present invention described herein with reference to the accompanying drawings may be implemented individually or in combination. However, these embodiments are provided for illustrative purposes only and are not intended to limit the scope of the invention. It should be understood that various modifications, substitutions, equivalents, and alterations may be made without departing from the spirit and scope of the invention. Any functions, features, or embodiments disclosed herein may be implemented independently or in combination with other embodiments. Accordingly, the scope of the invention is not limited to the specific embodiments illustrated in the drawings.

Terms such as “first,” “second,” and the like may be used to distinguish one element from another and do not imply any particular order, priority, or limitation.

The terminology used in the description of the embodiments is intended solely to describe specific examples and is not intended to limit the invention. Unless clearly indicated otherwise, singular expressions are intended to include the plural, and vice versa. Terms such as “include,” “comprise,” “have,” and variations thereof are intended to be inclusive and non-limiting, indicating the presence of stated features, elements, steps, or components without excluding the possibility of additional or alternative features, elements, steps, or components.

When an element or layer is described as being “on,” “connected to,” or “coupled to” another element or layer, it may be directly or indirectly positioned, connected, or coupled, unless expressly stated as “directly on,” “directly connected to,” or “directly coupled to,” in which case no intervening elements or layers are present.

Spatially relative terms such as “above,” “below,” “upper,” “lower,” and similar expressions are used for descriptive convenience and refer to relationships as illustrated in the drawings. These terms are intended to encompass different orientations of the device or system during use, operation, or manufacture.

Hereinafter, embodiments of the present invention will be described in detail with reference to the accompanying drawings. Identical or similar components are denoted by the same reference numerals throughout the detailed description.

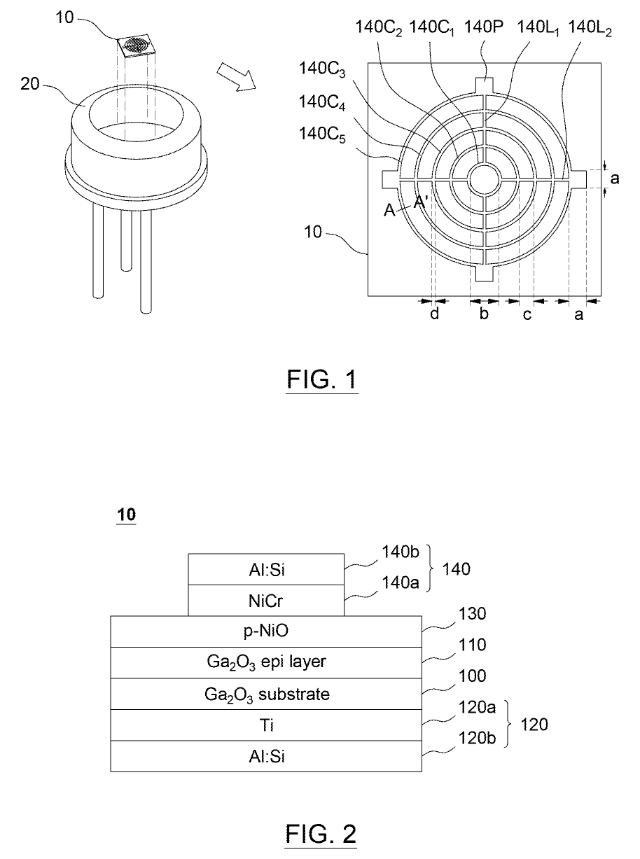

FIG. 1 illustrates one embodiment of a gallium oxide heterojunction-based DUV sensor.

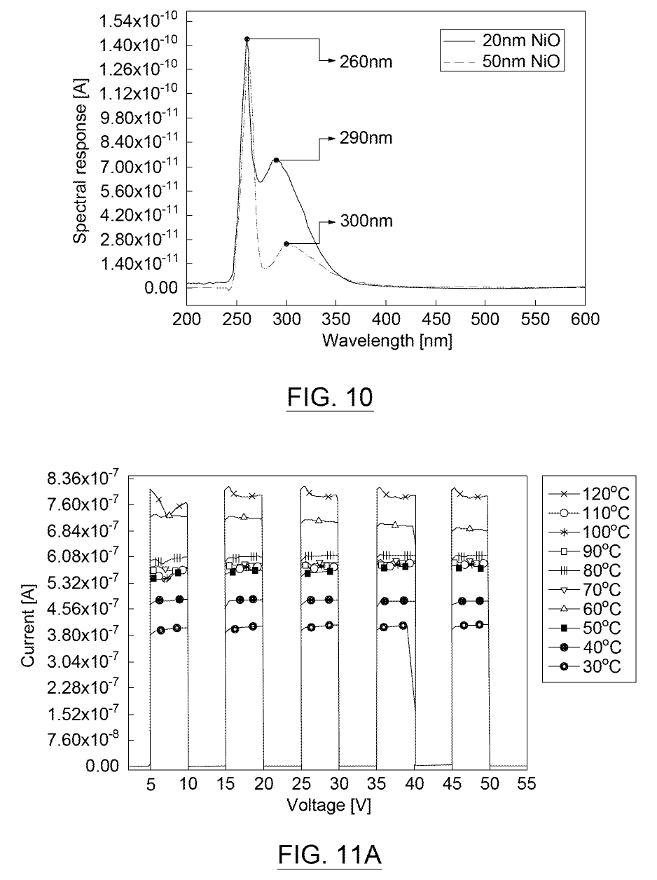

A gallium oxide heterojunction-based DUV sensor 10 may detect DUV rays and generate a photocurrent. The upper surface of the gallium oxide heterojunction-based DUV sensor 10 is configured to receive light rays including DUV, that are incident thereon. As shown FIGS. 2 and 10, a patterned top electrode 140 may be formed on a p-NiO layer 130 to prevent interference with the incidence of DUV onto the p-NiO layer 130.

The patterned top electrode 140 may be formed by two or more layers stacked vertically to form a current path with a bottom electrode 120 as shown in FIGS. 2 and 4. This path outputs the photocurrent generated by the DUV incident into the sensor. The patterned top electrode 140 may include a plurality of coaxial ring regions 140C₁ to 140C₅ sharing a common central axis. The plurality of coaxial ring regions 140C₁ to 140C₅ may be connected by connecting regions 140L₁, 140L₂. The connecting regions 140L₁, 140L₂ may extend from the innermost coaxial ring region 140C₁ to the outermost coaxial ring region 140C₅, be connected to all of the plurality of coaxial ring regions 140C₁ to 140C₅, but may be not formed inside the innermost coaxial ring region 140C₁. A pad region 140P is connected to one end of the connecting regions 140L₁, 140L₂ that is farther from the common central axis.

The pad region 140P may be formed as a square region a x a, where a may be about 150 μm. An inner diameter b of the first coaxial ring region 140C₁, located innermost among the plurality of coaxial ring regions 140C₁ to 140C₅, may be about 250 μm. A distance c between two neighboring coaxial ring regions among the plurality of coaxial ring regions 140C₁ to 140C₅ may be 1/2 of the inner diameter b. Meanwhile, a width d of the plurality of coaxial ring regions 140C₁ to 140C₅ and the connecting regions 140L₁, 140L₂ may be substantially the same and may be about 25 μm.

The gallium oxide heterojunction-based DUV sensor 10 may be disposed within a sensor package 20 and is electrically connected to output pins by wiring, for example. One end of the wire may be connected to the pad region 140P of the patterned top electrode 140, and the other end may be connected to an output pin. The bottom electrode 120 may be electrically fixed to the sensor package 20 using soldering, conductive paste or silver sintering.

FIG. 2 illustrates a cross-section of one embodiment of the gallium oxide heterojunction-based DUV sensor along AA' of FIG. 1.

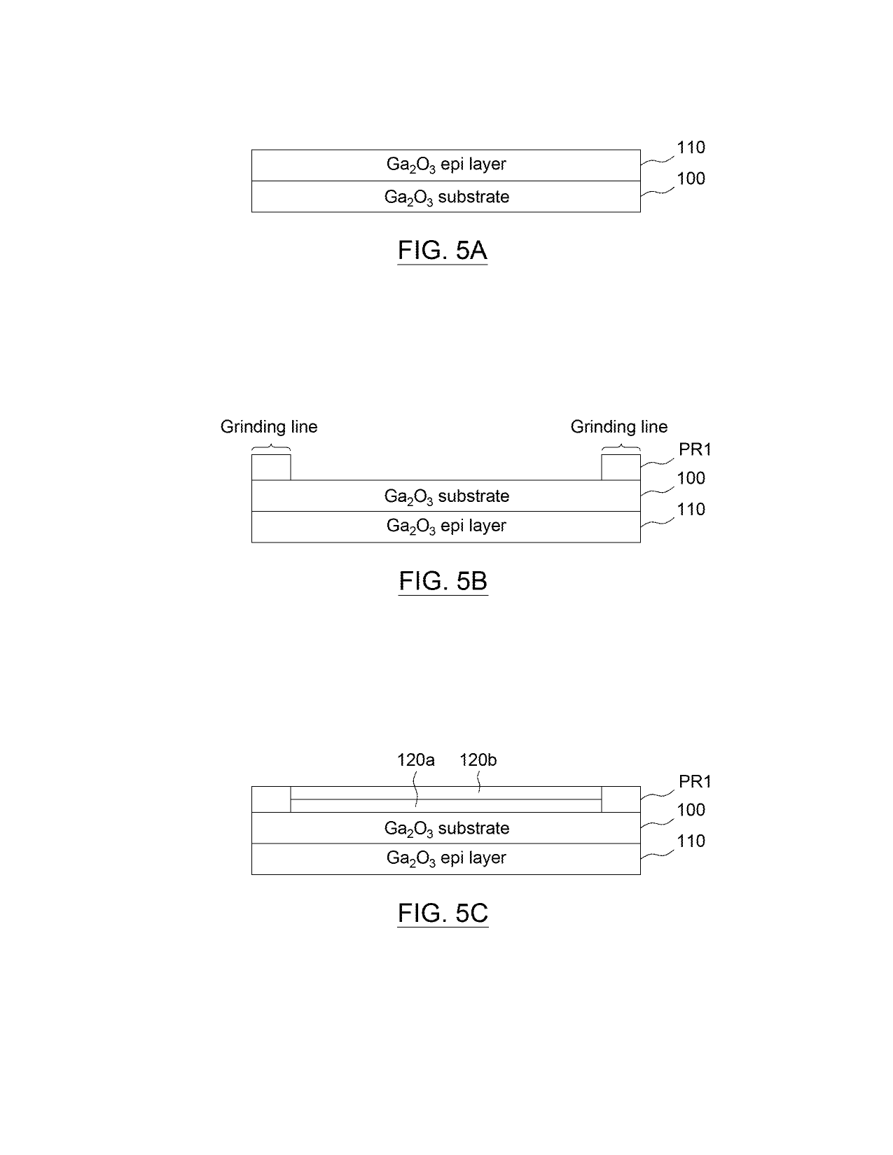

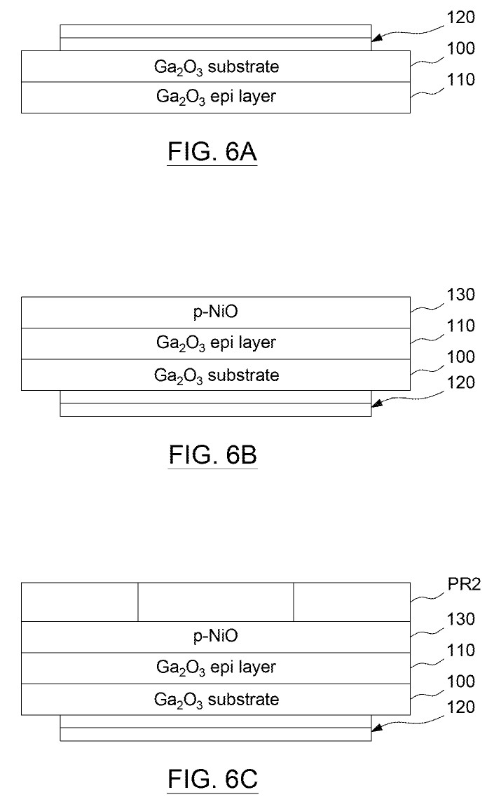

Referring to FIG. 2, the gallium oxide heterojunction-based DUV sensor 10 may include an n-type gallium oxide substrate 100, an n-type gallium oxide epitaxial layer 110, the bottom electrode 120, the p-type nickel oxide (p-NiO) layer 130, and the patterned top electrode 140. For the manufacturing process of the gallium oxide heterojunction-based DUV sensor 10, refer to FIGS. 5 and 6.

The n-type gallium oxide substrate 100 may be formed of gallium oxide (β-Ga₂O₃) doped with an n-type dopant. The n-type dopant may be, for example, Sn or Si, and the carrier concentration of the n-type gallium oxide substrate 100 may be about 4.0 × 10¹⁸cm⁻³. Meanwhile, the thickness of the n-type gallium oxide substrate 100 may be about 650 μm.

The n-type gallium oxide epitaxial layer 110 is a path through which photocurrent, generated by absorbing DUV, flows. It also forms a pn heterojunction with the p-type nickel oxide layer 130. The n-type gallium oxide epitaxial layer 110 may be formed by doping a gallium oxide layer grown epitaxially on the n-type gallium oxide substrate 100. The n-type dopant may be, for example, Si, and the carrier concentration of the n-type gallium oxide epitaxial layer 110 may be about 1.0 × 10¹⁶cm⁻³. The thickness of the gallium oxide epitaxial layer 110 may be about 5.0 μm. The n-type gallium oxide epitaxial layer 110 may be deposited by, for example, HVPE (Halide vapor phase epitaxy), MOCVD (Metalorganic chemical vapor deposition), Mist CVD, MBE (Molecular Beam Epitaxy), or PLD (Pulsed laser deposition).

The bottom electrode 120 may include two or more metal layers sequentially stacked on the bottom surface of the n-type gallium oxide substrate 100. In one embodiment, the bottom electrode 120 may include a titanium layer 120a having a thickness of about 150 nm, which is deposited on the bottom surface of the n-type gallium oxide substrate 100 to form an ohmic contact and an aluminum-silicon alloy layer 120b having a thickness of about 400 nm may be deposited on the titanium layer 120a. The aluminum-silicon alloy layer 120b exhibits improved oxidation resistance compared to a pure aluminum layer and may be bonded to the sensor package 20 via soldering, conductive paste, or silver sintering.

The p-type nickel oxide layer 130 may be deposited by sputtering using a nickel oxide target on the n-type gallium oxide epitaxial layer 110, thereby forming a pn heterojunction. The p-type nickel oxide layer 130 may have a thickness of about 20 nm and a carrier concentration of about 1.0 × 10¹⁹cm⁻³.

The patterned top electrode 140 may include the plurality of coaxial ring regions 140C₁ to 140C₅, connecting regions 140L₁, 140L₂, and a pad region 140P, which are formed by stacking two or more metal layers on the p-type nickel oxide layer 130. In one embodiment, the patterned top electrode 140 may include a nickel-chromium alloy layer 140a having a thickness of about 200 nm that is deposited on the p-type nickel oxide layer 130 to form an ohmic contact with the p-type nickel oxide layer 130, and an aluminum-silicon alloy layer 140b with a thickness of about 600 nm that is deposited on the nickel-chromium alloy layer 140a.

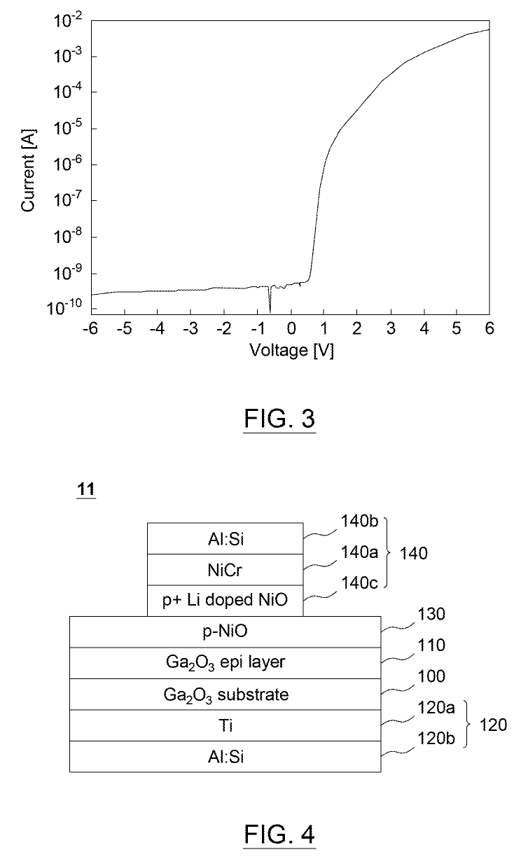

FIG. 3 is an I-V characteristic graph of the gallium oxide heterojunction-based DUV sensor illustrated in FIG. 2 under dark condition.

As shown in the I-V characteristic graph on a log scale, the gallium oxide heterojunction-based DUV sensor 10 exhibits the rectification characteristics of a pn heterojunction diode when a voltage of about -6V to +6V is applied to it in the dark.

FIG. 4 illustrates a cross-section of one embodiment of the gallium oxide heterojunction-based DUV sensor along AA' of FIG. 1.

Referring to FIG. 4, a gallium oxide heterojunction-based DUV sensor 11 may include an n-type gallium oxide substrate 100, an n-type gallium oxide epitaxial layer 110, a bottom electrode 120, a p-type nickel oxide layer 130, and a patterned top electrode 140.

The n-type gallium oxide substrate 100 may be formed of gallium oxide (β-Ga₂O₃) doped with an n-type dopant. The n-type dopant may be, for example, Sn or Si, and the carrier concentration of the n-type gallium oxide substrate 100 may be about 4.0 × 10¹⁸cm⁻³. Meanwhile, the thickness of the n-type gallium oxide substrate 100 may be about 650 μm.

The n-type gallium oxide epitaxial layer 110 is a path through which photocurrent, generated by absorbing DUV, flows. It also forms a pn heterojunction with the p-type nickel oxide layer 130. The n-type gallium oxide epitaxial layer 110 may be formed by doping a gallium oxide layer grown epitaxially on the n-type gallium oxide substrate 100. The n-type dopant may be, for example, Si, and the carrier concentration of the n-type gallium oxide epitaxial layer 110 may be about 1.0 × 10¹⁶cm⁻³. The thickness of the gallium oxide epitaxial layer 110 may be about 5.0 μm. The n-type gallium oxide epitaxial layer 110 may be deposited by, for example, HVPE (Halide vapor phase epitaxy), MOCVD (Metalorganic chemical vapor deposition), Mist CVD, MBE (Molecular Beam Epitaxy), or PLD (Pulsed laser deposition).

The bottom electrode 120 may include two or more metal layers sequentially stacked on the bottom surface of the n-type gallium oxide substrate 100. In one embodiment, the bottom electrode 120 may include a titanium layer 120a having a thickness of about 150 nm, which is deposited on the bottom surface of the n-type gallium oxide substrate 100 to form an ohmic contact and an aluminum-silicon alloy layer 120b having a thickness of about 400 nm may be deposited on the titanium layer 120a. The aluminum-silicon alloy layer 120b exhibits improved oxidation resistance compared to a pure aluminum layer and may be bonded to the sensor package 20 via soldering, conductive paste, or silver sintering.

The p-type nickel oxide layer 130 may be deposited by sputtering using a nickel oxide target on the n-type gallium oxide epitaxial layer 110, thereby forming a pn heterojunction. The p-type nickel oxide layer 130 may have a thickness of about 20 nm and a carrier concentration of about 1.0 × 10¹⁹cm⁻³.

The patterned top electrode 140 may include the plurality of coaxial ring regions 140C₁ to 140C₅, connecting regions 140L₁, 140L₂, and a pad region 140P, which are formed by stacking two or more metal layers on the p-type nickel oxide layer 130. The patterned top electrode 140 may further include a contact resistance reducing layer having a relatively high dopant concentration interposed between the p-type nickel oxide layer 130 and the nickel-chromium alloy layer 140a to reduce contact resistance. In one embodiment, the patterned top electrode 140 may include a p+ Li-doped nickel oxide layer 140c having a thickness of about 150 nm, deposited on the p-type nickel oxide layer 130, a nickel-chromium alloy layer 140a having to a thickness of about 200 nm, deposited on the p+-type Li-doped nickel oxide layer 140c to form an ohmic contact with the p+ Li-doped nickel oxide layer 140c, and an aluminum-silicon alloy layer 140b having a thickness of about 600 nm, deposited on the nickel-chromium alloy layer 140a.

FIGS. 5A to 7B illustrate a manufacturing process of a gallium oxide heterojunction-based DUV sensor.

Referring to FIG. 5A, after preparing an n-type gallium oxide substrate 100 on which an n-type gallium oxide epitaxial layer 110 is formed, the substrate is cleaned to remove foreign substances. The n-type gallium oxide substrate 100 and the n-type gallium oxide epitaxial layer 110 may be formed of β-Ga₂O₃ doped with an n-type dopant. The n-type gallium oxide epitaxial layer 110 may be formed on the n-type gallium oxide substrate 100 by epitaxial growth. The thickness of the n-type gallium oxide substrate 100 is about 650 μm, and the carrier concentration may be about 4.0 × 10¹⁸ cm⁻³. Meanwhile, the thickness of the n-type gallium oxide epitaxial layer 110 may be. The thickness of the gallium oxide epitaxial layer 110 may be about 5.0 μm, and its carrier concentration may be about 1.0 × 10¹⁶ cm⁻³.

Organic contaminants may be removed from the surface of the n-type gallium oxide substrate 100 by ultrasonic treatment for about 5 minutes while immersed in acetone. Subsequently, residual organic contaminants and fine particles may be removed by ultrasonic treatment for about 5 minutes while immersed in isopropyl alcohol (IPA). The n-type gallium oxide substrate 100 may then be rinsed with distilled water to remove residual chemicals. Thereafter, the n-type gallium oxide substrate 100 may be cleaned using a buffered oxide etchant (BOE), followed by another rinse with distilled water. To further eliminate remaining organic contaminants, the substrate may be irradiated with ultraviolet C (UVC) light for about 24 hours. Finally, a thin oxide film formed on the n-type gallium oxide epitaxial layer 110 may be removed by dry etching.

Referring to FIG. 5B, a bottom electrode pattern PR1 for forming a bottom electrode 120 may be formed on the bottom surface of the n-type gallium oxide substrate 100. The bottom electrode pattern PR1 may define a grinding line, and the bottom electrode 120 may be formed in the area excluding the grinding line defined by the pattern PR1. In one embodiment, the bottom electrode pattern PR1 may be formed by spin-coating a liquid photoresist onto the substrate, followed by soft baking, exposure, and development processes.

Referring to FIG. 5C, two or more metal layers may be successively deposited on the bottom surface of the n-type gallium oxide substrate 100. By DC sputtering in Ar gas atmosphere, the titanium layer 120a having a thickness of about 150 nm may be deposited on the bottom surface of the n-type gallium oxide substrate 100, and the aluminum-silicon alloy layer 120b having a thickness of about 400 nm may be deposited on the bottom surface of the n-type gallium oxide substrate 100. The aluminum-silicon alloy target may have a composition ratio of about 99 wt% aluminum and 1 wt% silicon. During the sputtering process, the base pressure may be about 3x10⁻⁶ Torr, the working pressure may be about 5 mTorr, the Ar flow rate may be about 20 sccm, and the temperature may be maintained at room temperature.

Referring to FIG. 6A, the bottom electrode 120 may be formed by removing the bottom electrode pattern PR1. For example, the bottom electrode pattern PR1 may be removed by a lifted-off process, thereby eliminating the metal layer deposited on the bottom electrode pattern PR1 formed along the grinding line. After the removal of the pattern PR1, UVC irradiation may be applied to the n-type gallium oxide epitaxial layer 110 to eliminate residual organic contaminants.

Referring FIG. 6B, a p-type nickel oxide layer 130 may be formed on the n-type gallium oxide epitaxial layer 110. The p-type nickel oxide layer 130 may have a thickness of about 20 nm and may be deposited by radio-frequency (RF) sputtering using a nickel oxide target in Ar-O₂ mixed gas atmosphere. During the sputtering process, the base pressure may be about 3x10⁻⁶ Torr, the working pressure may be about 5 mTorr, the Ar flow rate may be about 20 sccm, the O₂ flow rate may be about 4 sccm, and the temperature may be maintained at room temperature.

Referring to FIG. 6C, a top electrode pattern PR2 for forming the patterned top electrode 140 may be formed on the p-type nickel oxide layer 130. The pattern PR2 may be formed by spin-coating a liquid photoresist, followed by soft baking, photo, and etching processes. Through the photo and etching process, the photoresist in the regions corresponding to the coaxial ring regions 140C₁ to 140C₅, connecting regions 140L1 and 140L₂, and pad region 140P may be removed, thereby exposing the underlying p-type nickel oxide layer 130.

Referring to FIG. 7A, two or more metal layers may be successively deposited on the p-type nickel oxide layer 130. When fabricating the gallium oxide heterojunction-based DUV sensor 11 illustrated in FIG. 4, a p+ Li-doped nickel oxide layer 140c having a thickness of about 150 nm may be deposited on the p-type nickel oxide layer 130 by RF sputtering using a Li-doped nickel oxide target in Ar-O₂ mixed gas atmosphere. During this sputtering process, the base pressure may be about 3x10⁻⁶ Torr, the working pressure may be about 5 mTorr, the argon flow rate may be about 20 sccm, the oxygen flow rate may be about 4 sccm, and the temperature may be maintained at room temperature.

A nickel-chromium alloy layer 140a having a thickness of about 200 nm may then be deposited on the Li-doped nickel oxide layer 140c by DC sputtering using a nickel-chromium target in Ar atmosphere. Subsequently, an aluminum-silicon alloy layer 140b having a thickness of about 600 nm may be deposited on the nickel-chromium alloy layer 140a by DC sputtering using an aluminum-silicon alloy target in Ar atmosphere. The nickel-chromium target may contain about 80 wt% nickel and 20 wt% chromium. The presence of chromium enhances adhesion to the underlying Li-doped nickel oxide layer 140c, thereby improving mechanical stability and reducing electrode delamination during subsequent processes such as wiring and device operation.

In one embodiment, when fabricating the gallium oxide heterojunction-based DUV sensor 10 illustrated in FIG. 2, the forming of the p+ Li-doped nickel oxide layer 140c may be omitted. In this case, a nickel-chromium alloy layer 140a having a thickness of about 200 nm may be deposited directly on the p-type nickel oxide layer 130 by DC sputtering using a nickel-chromium target in Ar atmosphere. Subsequently, the aluminum-silicon alloy layer 140b having a thickness of about 600 nm may be deposited on the nickel-chromium alloy layer 140a by DC sputtering using an aluminum-silicon alloy target in Ar atmosphere.

Referring to FIG. 7B, the top electrode 140 may be formed by removing the top electrode pattern PR2. For example, the top electrode pattern PR2 may be removed by a lift-off process, thereby eliminating the metal layer deposited in the areas excluding the regions corresponding to the coaxial ring regions 140C₁ to 140C₅, the connecting regions 140L₁ and 140L₂, and the pad region 140P.

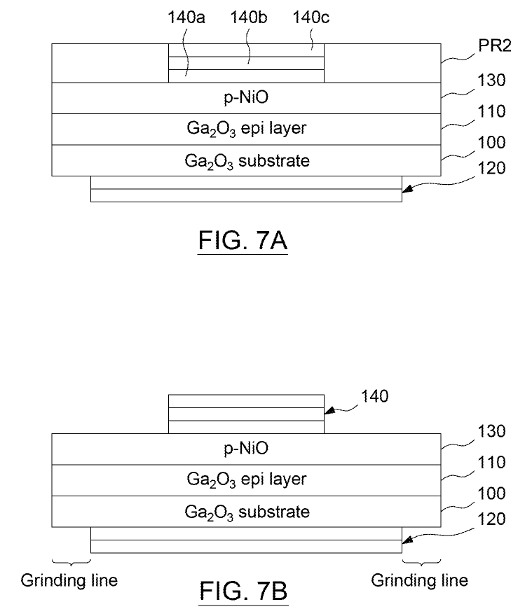

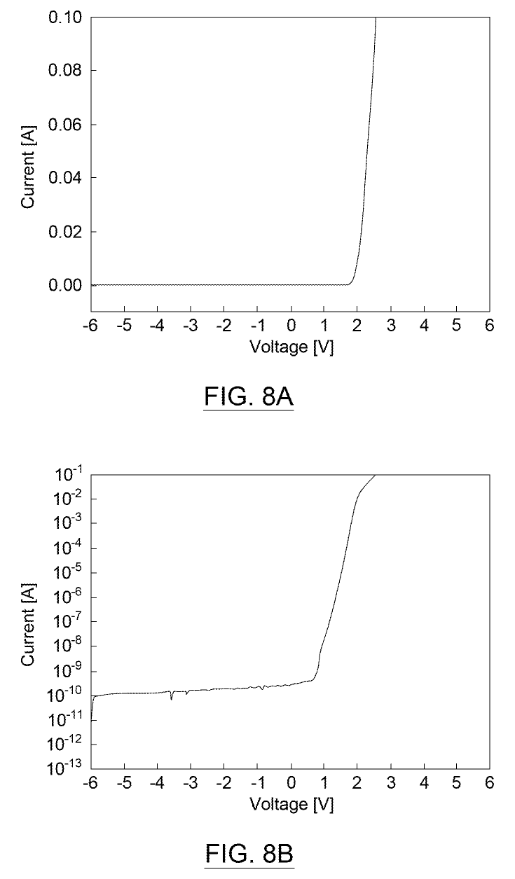

FIG. 8A and FIG. 8B are graphs illustrating I-V characteristics of the gallium oxide heterojunction-based DUV sensor, as shown in FIG. 4, measured under dark conditions.

Referring to FIGS. 8A and 8B, I-V characteristic graphs of the gallium oxide heterojunction-based DUV sensor 11, measured under dark conditions with an applied voltage ranging from about −6 V to +3 V, are shown in linear scale (FIG. 8A) and logarithmic scale (FIG. 8B). These graphs confirm that the sensor exhibits rectification behavior characteristic of a pn heterojunction diode. In particular, when comparing FIG. 8B with FIG. 3, the slope of the I-V curve increases significantly under forward bias conditions, indicating the effectiveness of the contact resistance reducing layer. The p+ Li-doped nickel oxide layer 140c, having a hole concentration of about 1E20cm⁻³, may be deposited on the p-type nickel oxide layer 130 and forms an ohmic junction with the nickel-chromium alloy layer 140a. This structure demonstrates lower contact resistance compared to conventional p-NiO/NiCr interfaces. The reduced contact resistance contributes to enhanced photocurrent generation, which is beneficial for arc detection applications. Furthermore, a multilayer structure including the p-type nickel oxide layer and p+ Li-doped nickel oxide layer improves reverse-bias characteristics, including reduced leakage current and increased breakdown voltage.

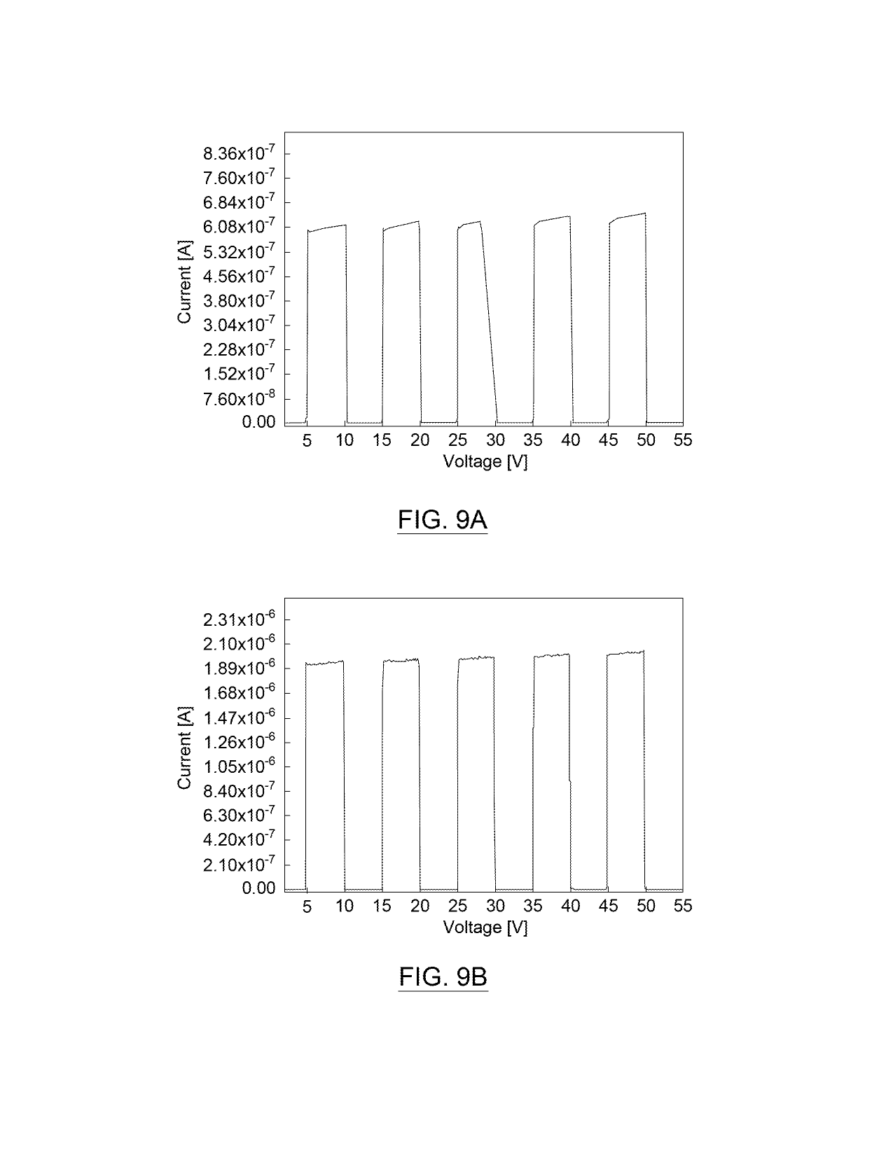

FIG. 9A and FIG. 9B are graphs illustrating exemplary photocurrent responses of the gallium oxide heterojunction-based DUV sensor as a function of UV wavelength.

FIG. 9A illustrates the photocurrent response of the gallium oxide heterojunction-based DUV sensor when irradiated with light having a wavelength of about 254 nm and an intensity of about 1,000 μW/cm² at regular time intervals. FIG. 9B illustrates the photocurrent response of the same sensor when irradiated with light having a wavelength of about 222 nm at regular time intervals. Under 254 nm DUV irradiation, the measured photocurrent (i.e., on-current) is about 5 x 10⁻⁷ A to 7 x 10⁻⁷ A, while the dark current (i.e., off-current) is about 5 x 10⁻¹¹ A to 7 x 10⁻¹¹ A, resulting in an on/off current ratio of about 7.1 x 10³ to 1.4 x 10⁴. Under 222 nm DUV irradiation, the on-current is about 1.7 × 10⁻⁶ to 2.0 × 10⁻⁶ A, and the off-current is about 1.0 × 10⁻¹⁰ to 2.0 × 10⁻¹⁰ A, yielding an on/off current ratio of about 8.5 × 10³ to 1.1 × 10⁴.

FIG. 10 is a graph illustrating an exemplary responsivity of a gallium oxide heterojunction-based DUV sensor as a function of UV wavelength.

Referring to FIG. 10, the graph illustrates the responsivity of a gallium oxide heterojunction-based DUV sensor under a bias voltage of about 5 V, when irradiated with UV having wavelengths ranging from about 200 nm to 600 nm at an intensity of about 1,000 μW/cm². Two DUV sensors were fabricated with p-type nickel oxide layers having thicknesses of about 20 nm and 50 nm, respectively. When irradiated with UV in the range of about 250 nm to 350 nm, which partially overlaps with the DUV wavelength band, both sensors generated a photocurrent. A primary responsivity peak was observed at about 260 nm in both sensors. Additionally, a secondary peak was detected at about 290 nm in the sensor with the 20 nm-thick p-type nickel oxide layer, and at about 300 nm in the sensor with the 50 nm-thick layer. These results indicate that both thicknesses yield excellent DUV responsivity. However, the sensor with the thinner p-type nickel oxide layer exhibits a secondary peak at a shorter wavelength, suggesting enhanced spectral selectivity and relatively superior DUV responsivity.

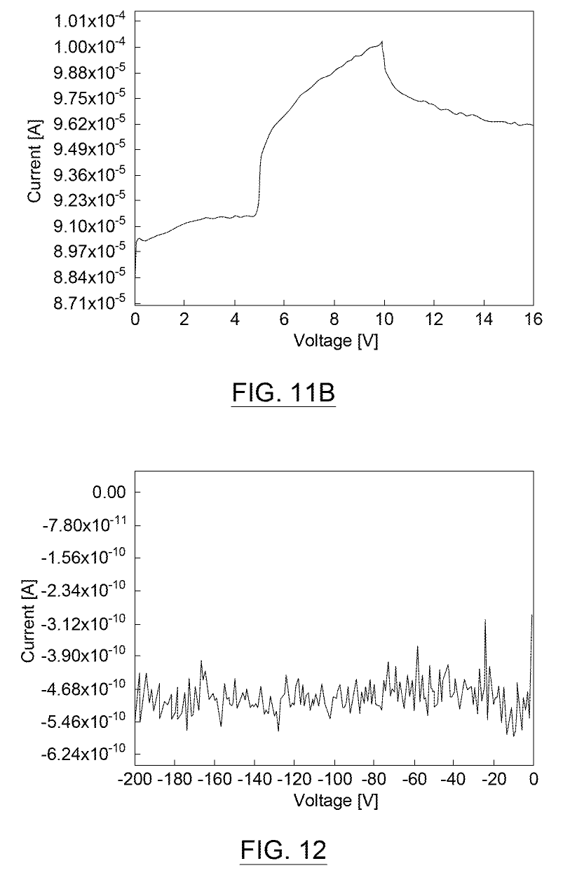

FIG. 11A and FIG. 11B are graphs illustrating exemplary photocurrent characteristics of the gallium oxide heterojunction-based DUV sensor as a function of temperature.

Referring to FIG. 11A, the graph illustrates the photocurrents (including on-current and off-current) of the gallium oxide heterojunction-based DUV sensor under a bias voltage of about 5 V, measured while varying the ambient temperature from about 30℃ to 120℃. The sensor was irradiated with ultraviolet light at an intensity of about 1,000 μW/cm². Although the magnitude of the photocurrent varies with temperature, a distinguishable on/off current ratio is maintained throughout this range.

In contrast, as shown in FIG. 11B, when the ambient temperature exceeds about 130°C under the same bias and irradiation conditions, the leakage current increases significantly. This results in a substantial reduction in the on/off current ratio, indicating abnormal operation of the DUV sensor at elevated temperatures.

FIG. 12 is a graph illustrating I-V characteristics of the gallium oxide heterojunction-based DUV sensor under reverse bias conditions.

Referring to FIG. 12, the leakage current of the gallium oxide heterojunction-based DUV sensor was measured under reverse bias conditions in the absence of light (i.e., in the dark). The leakage current is about 1 nA or less, and the breakdown voltage is greater than −200 V.

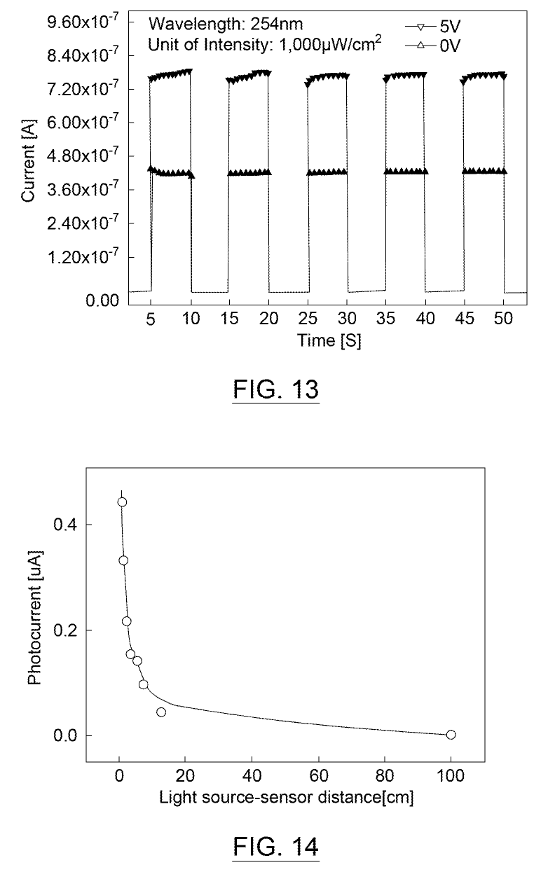

FIG. 13 is a graph illustrating the current characteristics of the gallium oxide heterojunction-based DUV sensor as a function of applied bias voltage.

Referring to FIG. 13, the photocurrents of the gallium oxide heterojunction-based DUV sensor were measured by irradiating light with a wavelength of about 254 nm at an intensity of about 1,000 μW/cm² at regular time intervals, under bias voltages of 0 V and 5 V. Under 254 nm DUV irradiation, the on-current of the sensor at 0 V bias was measured to be about 4.2 × 10⁻⁷ A, while the on-current at 5 V bias increased to about 7.8 × 10⁻⁷ A. In the absence of light, the measured current was nearly 0 A in both cases. These results confirm that applying a positive bias voltage enhances the photocurrent and increases the on/off current ratio, thereby improving the sensor’s DUV detection performance

FIG. 14 is a graph illustrating the photocurrent characteristics of the gallium oxide heterojunction-based DUV sensor as a function of the distance between the sensor and a light source.

Referring to FIG. 14, the photocurrent of the gallium oxide heterojunction-based DUV sensor was measured while varying the distance between the sensor and a light source emitting DUV radiation at a wavelength of about 254 nm and an intensity of about 1,000 μW/cm². A bias voltage of about 5 V was applied during the measurement. As expected, the photocurrent decreases as the distance from the light source increases, confirming the sensor’s distance-dependent responsivity to DUV irradiation

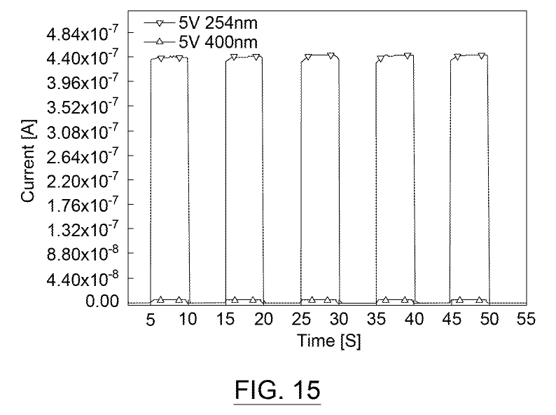

FIG. 15 is a graph illustrating the photocurrent characteristics of the gallium oxide heterojunction-based DUV sensor as a function of incident light wavelength.

Referring to FIG. 15, the photocurrent of the gallium oxide heterojunction-based DUV sensor was measured by placing the sensor within a sensor package 20, applying a bias voltage of approximately 5 V, and irradiating light at regular time intervals with wavelengths of approximately 254 nm (DUV) and 400 nm (UVA), each at an intensity of approximately 1,000 μW/cm². A comparison of the photocurrent responses reveals that the photocurrent generated under 254 nm DUV irradiation is approximately 100 times greater than that generated under 400 nm UVA irradiation. This result confirms that the DUV-to-UVA (or UVB) rejection ratio of the sensor is exceptionally high, demonstrating its strong wavelength selectivity and suitability for DUV-specific detection applications.

The foregoing description of the embodiments of the present invention is provided for purposes of illustration and is not intended to be exhaustive or to limit the invention to the precise forms disclosed. It will be understood by those skilled in the art that various modifications, additions, and substitutions are possible without departing from the spirit and scope of the invention.

Accordingly, the scope of the present invention should be defined by the appended claims and their equivalents, rather than by the foregoing detailed description. All modifications and variations that fall within the meaning and range of equivalency of the claims are intended to be embraced therein.

What is claimed is:

1. A gallium oxide heterojunction-based DUV sensor, comprising:
an n-type gallium oxide substrate;
an n-type gallium oxide epitaxial layer disposed on the n-type gallium oxide substrate;
a p-type nickel oxide layer disposed on the n-type gallium oxide epitaxial layer and configured to form a pn heterojunction with the n-type gallium oxide epitaxial layer;
a patterned top electrode disposed on the p-type nickel oxide layer; and
a bottom electrode disposed on a bottom surface of the n-type gallium oxide substrate.

2. The gallium oxide heterojunction-based DUV sensor of claim 1, wherein the patterned top electrode comprises:
a plurality of coaxial ring regions sharing a common central axis;
a connecting region extending from an innermost coaxial ring region to an outermost coaxial ring region and electrically connected to each of the plurality of coaxial ring regions; and
a pad region connected to a distal end of the connecting region, the distal end being farthest from the common central axis.

3. The gallium oxide heterojunction-based DUV sensor of claim 1, wherein the patterned top electrode comprises:
a nickel-chromium alloy layer disposed on the p-type nickel oxide layer and configured to form an ohmic contact with the p-type nickel oxide layer; and
an aluminum-silicon alloy layer disposed on the nickel-chromium alloy layer.

4. The gallium oxide heterojunction-based DUV sensor of claim 3, wherein the aluminum-silicon alloy layer has a weight ratio of aluminum to silicon of 99:1.

5. The gallium oxide heterojunction-based DUV sensor of claim 1, wherein the patterned top electrode comprises:
a p-type contact resistance reducing layer disposed on the p-type nickel oxide layer and configured to reduce contact resistance;
a nickel-chromium alloy layer disposed on the p-type contact resistance reducing layer; and
an aluminum-silicon alloy layer disposed on the nickel-chromium alloy layer.

6. The gallium oxide heterojunction-based DUV sensor of claim 5, wherein the p-type contact resistance reducing layer comprises a Li-doped nickel oxide layer having a carrier concentration greater than that of the p-type nickel oxide layer.

7. The gallium oxide heterojunction-based DUV sensor of claim 5, wherein a thickness of the p-type contact resistance reducing layer is less than a thickness of the nickel-chromium alloy layer.

8. The gallium oxide heterojunction-based DUV sensor of claim 5, wherein the aluminum-silicon alloy layer has a weight ratio of aluminum to silicon of 99:1.

9. The gallium oxide heterojunction-based DUV sensor of claim 1, wherein the bottom electrode comprises:
a titanium layer disposed on the bottom surface of the n-type gallium oxide substrate and configured to form an ohmic contact; and
an aluminum-silicon alloy layer disposed on the titanium layer.

10. A method of manufacturing a gallium oxide heterojunction-based DUV sensor, comprising:
providing an n-type gallium oxide substrate having an n-type gallium oxide epitaxial layer formed thereon;
forming a bottom electrode on a bottom surface of the n-type gallium oxide substrate;
forming a p-type nickel oxide layer on the n-type gallium oxide epitaxial layer; and
forming a patterned top electrode on the p-type nickel oxide layer.

11. The method of claim 10, wherein forming the patterned top electrode on the p-type nickel oxide layer comprises:
forming a top electrode pattern on the p-type nickel oxide layer, the top electrode pattern comprising a plurality of coaxial ring regions, a connecting region connected to the plurality of coaxial ring regions, and a pad region connected to the connecting region;
depositing a nickel-chromium alloy layer on the p-type nickel oxide layer via sputtering using a nickel-chromium alloy target;
depositing an aluminum-silicon alloy layer on the nickel-chromium alloy layer via sputtering using an aluminum-silicon alloy target; and
removing the top electrode pattern.

12. The method of claim 10, wherein forming the patterned top electrode on the p-type nickel oxide layer comprises:
forming a top electrode pattern on the p-type nickel oxide layer, the top electrode pattern comprising a plurality of coaxial ring regions, a connecting region connected to the plurality of coaxial ring regions, and a pad region connected to the connecting region;
depositing a p-type Li-doped nickel oxide layer on the p-type nickel oxide layer via sputtering using a Li-doped nickel oxide target;
depositing a nickel-chromium alloy layer on the p-type Li-doped nickel oxide layer via sputtering using a nickel-chromium alloy target;
depositing an aluminum-silicon alloy layer on the nickel-chromium alloy layer via sputtering using an aluminum-silicon alloy target; and
removing the top electrode pattern.
